(19) United States
(12) Patent Application Publication
(10) Pub. No.: US 2020/0208260 A1
(43) Pub. Date: Jul. 2, 2020

(54) Method of Forming RuSi Film and Film and Film-Forming Apparatus

(71) Applicant: TOKYO ELECTRON LIMITED, Tokyo (JP)

(72) Inventors: Takamichi KIKUCHI, Nirasaki City (JP); Naotaka NORO, Boise, ID (US); Toshio HASEGAWA, Nirasaki City (JP)

(21) Appl. No.: 16/727,147

(22) Filed: Dec. 26, 2019

(30) Foreign Application Priority Data
Dec. 27, 2018 (JP) 2018-245902

(51) Int. Cl. C23C 16/16; C23C 16/455; C23C 16/54; C23C 16/52

(52) U.S. Cl. CPC C23C 16/16; C23C 16/52; C23C 16/54; C23C 16/45527

(57) ABSTRACT

A method of forming a RuSi film includes performing a process a plurality of times, the process including alternately repeating: supplying a Ru(DMBD)(CO)₃ gas into a processing container accommodating a substrate; and supplying a hydrogenated silicon gas into the processing container.

### CROSS-REFERENCE TO RELATED APPLICATION

This application is based upon and claims the benefit of priority from Japanese Patent Application No. 2018-245902, filed on Dec. 27, 2018, the entire contents of which are incorporated herein by reference.

### TECHNICAL FIELD

The present disclosure relates to a method of forming a RuSi film and a film-forming apparatus.

### BACKGROUND

A method of forming a ruthenium-containing film through atomic layer deposition using Ru(DMBD)(CO)₃ as a raw material is known (e.g., see Patent Document 1).

### PRIOR ART DOCUMENT

### [Patent Document]

Japanese Patent Application Publication No. 2011-522124.

### SUMMARY

According to an embodiment of the present disclosure, a method of forming a RuSi film is provided. The method includes performing a process a plurality of times, the process including alternately repeating: supplying a Ru(DMBD)(CO)₃ gas into a processing container accommodating a substrate; and supplying a hydrogenated silicon gas into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing an example of a method of forming a RuSi film.

FIG. 2 is a diagram showing an exemplary configuration of a film-forming apparatus that forms a RuSi film.

FIG. 3 is an illustrative diagram of a gas supply sequence when a RuSi film is formed by using the film-forming apparatus of FIG. 2.

FIG. 4 is a diagram showing a relationship between a set number of times and Si in a RuSi film.

FIG. 5 is a diagram showing a relationship between a set number of times and resistivity of a RuSi film.

FIG. 6 is a diagram showing a relationship between a total supply time of Ru(DMBD)(CO)₃ gas and a film thickness of a RuSi film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereafter, a non-limitative exemplary embodiment of the present disclosure is described with reference to the accompanying drawings. The same or corresponding members or parts are given the same or corresponding reference numerals throughout the accompanying drawings and repeated description is omitted.

### [Method of Forming RuSi Film]

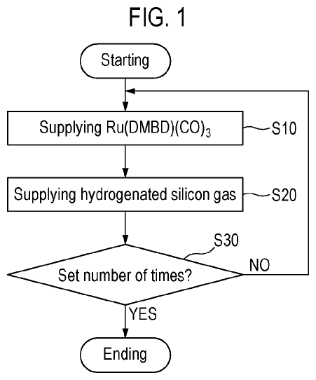

A method of forming a ruthenium silicide (RuSi) film of an embodiment of the present disclosure is described. FIG. 1 is a flowchart showing an example of a method of forming a RuSi film.

The method of forming a RuSi film of the embodiment of the present disclosure is a method that alternately repeats a step S10 and a step S20 until a set number of times is reached. Step S10 is a step of supplying gasified η4-2,3-dimethylbutadiene ruthenium tricarbonyl (Ru(DMBD)(CO)₃) into a processing container accommodating a substrate. Step S20 is a step of supplying hydrogenated silicon gas into the processing container. Further, it may be possible to perform a purge step of purging the processing container by supplying an inert gas such as nitrogen (N₂) gas and argon (Ar) gas between the step S10 and the step S20. Hereafter, each of the steps will be described.

In step S10, the substrate is accommodated into the processing container, the substrate is heated to a predetermined temperature, and then gasified Ru(DMBD)(CO)₃ is supplied into the processing container. Hereafter, the gasified Ru(DMBD)(CO)₃ is referred to as Ru(DMBD)(CO)₃ gas. The predetermined temperature may be 200 degrees C. or more in that it is possible to deposit ruthenium (Ru) on the substrate by sufficiently thermally decomposing Ru(DMBD)(CO)₃ gas in some embodiments, and it may be 300 degrees C. or less in terms of controllability of a film thickness in some embodiments.

As a method of supplying Ru(DMBD)(CO)₃ gas into the processing container, for example, it is possible to use a method of supplying Ru(DMBD)(CO)₃ gas stored in a storage tank into the processing container by opening/closing a valve disposed between the processing container and the storage tank (hereinafter, referred to as a fill-flow). As described above, when Ru(DMBD)(CO)₃ gas stored in the storage tank is supplied to the processing container by opening/closing the valve disposed between the processing container and the storage tank, it is possible to adjust the film thickness step by step in accordance with a valve opening/closing time and the number of times the valve is opened and closed, so there is an effect that it is possible to improve controllability of the film thickness.

Further, as the method of supplying Ru(DMBD)(CO)₃ gas into the processing container, for example, a method of continuously supplying Ru(DMBD)(CO)₃ gas into the processing container (hereinafter, referred to as a “continuous flow”) may be used. In other words, a method of supplying Ru(DMBD)(CO)₃ gas into the processing container without storing the Ru(DMBD)(CO)₃ gas in the storage tank may be used. As described above, since Ru(DMBD)(CO)₃ gas is supplied into the processing container without being stored in the storage container, it is possible to continuously form a Ru film, whereby it is possible to improve a film-forming rate.

In step S20, the substrate is accommodated in the processing container which is the same as that in step S10, the substrate is heated to a predetermined temperature, and then hydrogenated silicon gas is supplied into the processing container. The predetermined temperature may be the same or substantially the same as that in the step S10, for example, may be in the range of 200 degrees C. to 300 degrees C. in terms of productivity in some embodiments. The hydrogenated silicon gas, for example, includes at least one gas selected from a group including monosilane (SiH₄) and disilane (Si₂H₆).

As a method of supplying hydrogenated silicon gas into the processing container, for example, a method of supplying hydrogenated silicon gas stored in a storage tank into the processing container by opening/closing a valve disposed in the processing container and the storage tank may be used. As described above, when the hydrogenated silicon gas stored in the storage tank is supplied into the processing container by opening/closing the valve disposed between the processing container and the storage tank, it is possible to control a flow rate and a flow speed of the hydrogenated silicon gas in accordance with a valve opening/closing time and the number of times the valve is opened and closed. Accordingly, a controllability of the flow rate and the flow speed of the hydrogenated silicon gas is improved. Further, the valve is closed within short time after the valve is opened and then a mass of gas is introduced into the processing container, so there is little influence by a pressure of a subsequent gas and the mass of gas is more uniformly diffused in the processing container, as compared with when the gas is continuously supplied. Accordingly, it is possible to improve in-plane uniformity in silicidation.

Further, as the method of supplying the hydrogenated silicon gas into the processing container, for example, a method of continuously supplying the hydrogenated silicon gas into the processing container may be used. In other words, a method of supplying the hydrogenated silicon gas into the processing container without storing the hydrogenated silicon gas in the storage tank may be used. When the hydrogenated silicon gas is supplied into the processing container without storing the hydrogenated silicon gas in the storage tank, as described above, it is possible to continuously supply the hydrogenated silicon gas, so it is possible to improve a silicidation rate.

In step S30, it is determined whether a cycle including the step S10 to the step S20 has been performed by a predetermined set number of times. For example, the set number of times is determined depending on a desired film thickness of a RuSi film to be formed. In step S30, when the set number of times is reached, the process ends, and when the set number of times is not reached, the process returns to step S10.

According to a method of forming a RuSi film of an embodiment of the present disclosure, a step S10 of supplying Ru(DMBD)(CO)₃ gas into a processing container accommodating a substrate and a step S20 of supplying hydrogenated silicon gas into the processing container are alternately repeated a plural number of times. Accordingly, it is possible to change a ratio of a supply amount of the hydrogenated silicon gas to a supply amount of the Ru(DMBD)(CO)₃ gas by adjusting at least one of a time for which the Ru(DMBD)(CO)₃ gas is supplied and a time for which the hydrogenated silicon gas is supplied. As a result, a ratio of silicon (Si) contained in the RuSi film is changed, so it is possible to control a resistivity of the RuSi film.

For example, it is assumed that a total supply time of Ru(DMBD)(CO)₃ gas is fixed to 560 seconds for a plurality of cycles and the supply amount of hydrogenated silicon gas per cycle is fixed. In this case, when the time of step S10, that is, the supply time of the Ru(DMBD)(CO)₃ gas per cycle is decreased, the set number of times of step S30 is increased. Accordingly, the number of times of performing step S20 is increased, and the supply amount of the hydrogenated silicon gas with respect to the supply amount of the Ru(DMBD)(CO)₃ gas is increased. As a result, the ratio of Si contained in the RuSi film increases and the resistivity of the RuSi film increases. On the other hand, when the time of step S10, that is, the supply time of the Ru(DMBD)(CO)₃ gas per cycle is increased, the set number of times of step S30 is decreased. Accordingly, the number of times of performing step S20 is decreased, and the supply amount of the hydrogenated silicon gas with respect to the supply amount of the Ru(DMBD)(CO)₃ gas is decreased. As a result, the ratio of Si contained in the RuSi film decreases, and the resistivity of the RuSi film decreases.

### [Film-Forming Apparatus]

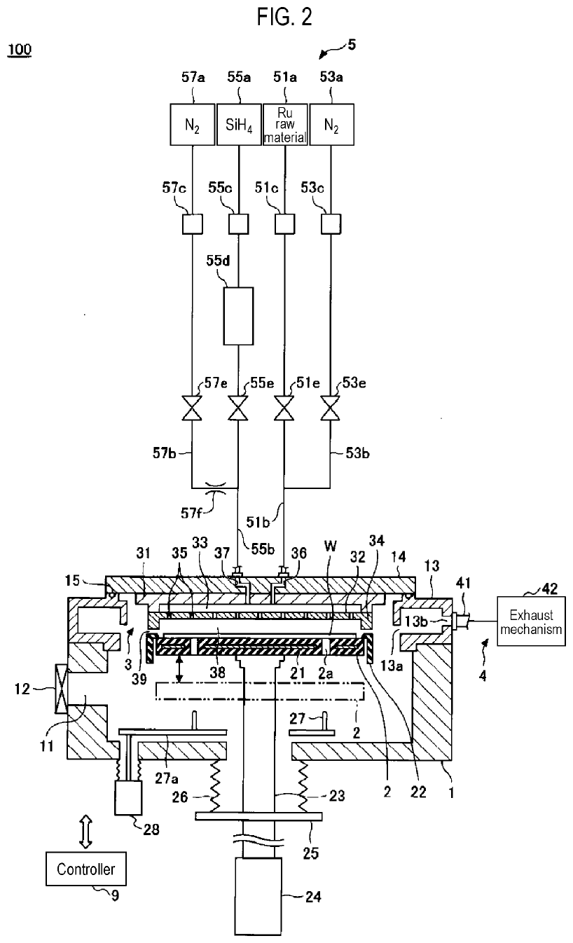

An example of a film-forming apparatus that may appropriately perform a method of forming a RuSi film of an embodiment of the present disclosure is described. FIG. 2 is a diagram showing an exemplary configuration of a film-forming apparatus that forms a RuSi film.

A film-forming apparatus 100 is an apparatus that can form a RuSi film using Atomic Layer Deposition (ALD) or Chemical Vapor Deposition (CVD) in a processing container that is in a decompression state.

The film-forming apparatus 100 includes a processing container 1, a stage 2, a shower head 3, an exhaust part 4, a gas supply mechanism 5, and a controller 9.

The processing container 1 is made of a metal such as aluminum and has a substantially cylindrical shape. The processing container 1 accommodates a semiconductor wafer (hereafter, referred to as a “wafer W”) as an example of the substrate. A loading/unloading port 11 configured to load or unload the wafer W is formed through a side wall of the processing container 1. The loading/unloading port 11 is opened/closed by a gate valve 12. A circular ring-shaped exhaust duct 13 having a rectangular cross-section is disposed on a body of the processing container 1. A slit 13a is formed on an inner circumferential surface of the exhaust duct 13. An exhaust port 13b is formed on an outer side wall of the exhaust duct 13. A ceiling wall 14 is disposed on an upper surface of the exhaust duct 13 so as to close an upper opening of the processing container 1. A seal ring 15 is hermetically disposed between the exhaust duct 13 and the ceiling wall 14.

The stage 2 horizontally supports the wafer W in the processing container 1. The stage 2 is formed in a disc shape having a size corresponding to the wafer W and is supported by a supporting member 23. The stage 2 is made of a ceramics material such as MN or a metal material such as aluminum or nickel alloy. A heater 21 configured to heat the wafer W is embedded inside the stage 2. The heater 21 is supplied with power from a heater power (not shown), thereby generating heat. An output of the heater 21 is controlled in response to a temperature signal from a thermocouple (not shown) disposed close to the upper surface of the stage 2, whereby the wafer W is controlled at a predetermined temperature. The stage 2 includes a cover member 22 made of ceramics such as alumina so as to cover an outer circumferential region and a side surface of the upper surface of the stage 2.

The supporting member 23 that supports the stage 2 is disposed on a bottom surface of the stage 2. The supporting member 23 extends from a center of the bottom surface of the stage 2 to a side under the processing container 1 through a hole formed through a bottom wall of the processing container 1, and a lower end of the supporting member 23 is connected to an elevator 24. The stage 2 is moved up and down through the supporting member 23 by the elevator 24 between a processing position shown in FIG. 2 and a transfer position (indicated by a two-dot chain line) under the processing position where the wafer W can be transferred. A flange 25 is attached to the supporting member 23 under the processing container 1. A bellows 26 that separates an atmosphere in the processing container 1 from an external air and stretches and contracts according to an elevation movement of the stage 2 is disposed between a bottom surface of the processing container 1 and the flange 25.

Three wafer support pins 27 (only two are shown) protruding upward from an elevation plate 27a are disposed close to the bottom surface of the processing container 1. The wafer support pins 27 are moved up and down through the elevation plate 27a by the elevator 28 disposed under the processing container 1. The wafer support pins 27 are inserted in through-holes 2a formed in the stage 2 that is at the transfer position to be able to protrude from to the upper surface of the stage 2. By moving up and down the wafer support pins 27, the wafer W is transferred between a transfer mechanism (not shown) and the stage 2.

The shower head 3 supplies a processing gas in a shower type into the processing container 1. The shower head 3 is made of metal. The shower head 3 is disposed to face the stage 2 and has a diameter substantially the same as that of the stage 2. The shower head 3 includes a body part 31 fixed to the ceiling wall 14 of the processing container 1 and a shower plate 32 connected to a lower portion of the body part 31. A gas diffusion space 33 is defined between the body part 31 and the shower plate 32. The gas diffusion space 33 is provided with gas inlet holes 36 and 37 formed through centers of the ceiling wall 14 of the processing container 1 and the body part 31. An annular protrusion 34 protruding downward is formed on a circumferential portion of the shower plate 32. Gas discharge holes 35 are formed through a flat surface inside the annular protrusion 34. When the stage 2 is at the processing position, a processing space 38 is defined between the stage 2 and the shower plate 32, and an upper surface of the cover member 22 and the annular protrusion 34 are closed to each other, thereby defining an annular gap 39.

The exhaust part 4 exhausts an inside of the processing container 1. The exhaust part 4 has an exhaust pipe 41 connected to the exhaust port 13b, and an exhaust mechanism 42 including a vacuum pump or a pressure control valve connected to the exhaust pipe 41. In processing, the gas in the processing container 1 reaches the exhaust duct 13 through the slit 13a and is then exhausted from the exhaust duct 13 through the exhaust pipe 41 by the exhaust mechanism 42.

The gas supply mechanism 5 supplies a processing gas into the processing container 1. The gas supply mechanism 5 has a Ru raw material gas supply source 51a, an N₂ gas supply source 53a, an SiH₄ gas supply source 55a, and an N₂ gas supply source 57a.

The Ru raw material gas supply source 51a supplies Ru(DMBD)(CO)₃ gas into the processing container 1 through a gas supply line 51b. The Ru raw material gas supply source 51a generates Ru(DMBD)(CO)₃ gas, for example, by evaporating (gasifying) Ru(DMBD)(CO)₃, which is in a liquid state at room temperature, stored in a liquid material tank, using a carrier gas (so-called a bubbling method). Hereafter, a flow rate of Ru(DMBD)(CO)₃ gas means a flow rate including a flow rate of the carrier gas that is used for generating Ru(DMBD)(CO)₃ gas. A flow rate controller 51c and a valve 51e are disposed in the gas supply line 51b from the upstream side. The downstream side of the valve 51e of the gas supply line 51b is connected to the gas inlet hole 36. The flow rate controller 51c controls the flow rate of Ru(DMBD)(CO)₃ gas that is supplied from the Ru raw material gas supply source 51a into the processing container 1. The valve 51e is opened and closed to control supply and stop of Ru(DMBD)(CO)₃ gas, which is supplied from the Ru raw material gas supply source 51a into the processing container 1. Further, although the storage tank is not installed in the gas supply line 51b in the example of FIG. 2, the storage tank may be installed between the flow rate controller 51c and the valve 51e, similar to a gas supply line 55b to be described below.

The N₂ gas supply source 53a supplies an N₂ gas that is a carrier gas into the processing container 1 through the gas supply line 53b and simultaneously supplies an N₂ gas that functions as a purge gas into the processing container 1. A flow rate controller 53c and a valve 53e are disposed in the gas supply line 53b from the upstream side. The downstream side of the valve 53e in the gas supply line 53b is connected to the gas supply line 51b. The flow rate controller 53c controls a flow rate of the N₂ gas that is supplied from the N₂ gas supply source 53a into the processing container 1. The valve 53e is opened and closed to control supply and stop of N₂ gas, which is supplied from the N₂ gas supply source 53a into the processing container 1. For example, the N₂ gas from the N₂ gas supply source 53a is continuously supplied into the processing container 1 during the film formation on the wafer W. Further, a purge gas supply line and a carrier gas supply line may be separately provided.

The SiH₄ gas supply source 55a supplies an SiH₄ gas, which is a hydrogenated silicon gas, into the processing container 1 through the gas supply line 55b. A flow rate controller 55c, a storage tank 55d, and a valve 55e are disposed in the gas supply line 55b from the upstream side. The downstream side of the valve 55e in the gas supply line 55b is connected to the gas inlet hole 37. The SiH₄ gas that is supplied from the SiH₄ gas supply source 55a is temporarily stored in the storage tank 55d and increased in pressure to a predetermined pressure in the storage tank 55d before it is supplied into the processing container 1, and is then supplied into the processing container 1. Supply and stop of the SiH₄ gas from the storage tank 55d to the processing container 1 are performed by opening/closing of the valve 55e. As described above, by temporarily storing the SiH₄ gas in the storage tank 55d, it is possible to stably supply the SiH₄ gas at a relatively high flow rate into the processing container 1.

The N₂ gas supply source 57a supplies an N₂ gas that is a carrier gas into the processing container 1 through a gas supply line 57b and simultaneously supplies an N₂ gas that functions as a purge gas into the processing container 1. A flow rate controller 57c, a valve 57e, and an orifice 57f are disposed in the gas supply line 57b from the upstream side. The downstream side of the orifice 57f in the gas supply line 57b is connected to the gas supply line 55b. The flow rate controller 57c controls a flow rate of the N₂ gas that is supplied from the N₂ gas supply source 57a into the processing container 1. The valve 57e is opened and closed to control supply and stop of the N₂ gas, which is supplied from the N₂ gas supply source 57a into the processing container 1. The orifice 57f suppresses a reverse flow of SiH₄ gas to the gas supply line 57b when the SiH₄ gas stored in the storage tank 55d is supplied into the processing container 1. The N₂ gas supplied from the N₂ gas supply source 57a is, for example, continuously supplied into the processing container 1 while a film is formed on the wafer W. Further, a purge gas supply line and a carrier gas supply line may be separately provided.

The controller 9 is, for example, a computer and includes a Central Processing Unit (CPU), a Random Access Memory (RAM), a Read Only Memory (ROM), auxiliary memory, and the like. The CPU operates on the basis of programs stored in the ROM or the auxiliary memory, and controls operation of the film-forming apparatus 100. The controller 9 may be disposed inside or outside the film-forming apparatus 100. When the controller 9 is disposed outside the film-forming apparatus 100, the controller 9 can control the film-forming apparatus 100 through a wire or wireless communication means.

### [Operation of Film-Forming Apparatus]

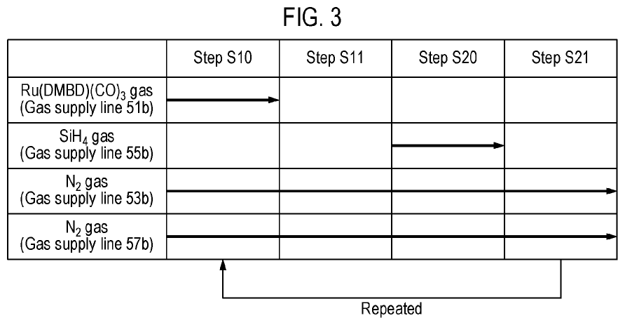

A method of forming a RuSi film using the film-forming apparatus 100 is described with reference to FIGS. 1 to 3. Hereinafter, the operation of the film-forming apparatus 100 is performed by the controller 9 controlling an operation of each part of the film-forming apparatus 100. FIG. 3 is an illustrative diagram of a gas supply sequence when forming the RuSi film using the film-forming apparatus 100 of FIG. 2.

First, when the gate valve 12 is opened with the valves Me, 53e, 55e, and 57e closed, the wafer W is transferred into the processing container 1 by a transfer mechanism (not shown) and is then mounted on the stage 2 at the transfer position. After the transfer mechanism retreats from the inside of the processing container 1, the gate valve 12 is closed. The wafer W is heated to a predetermined temperature by the heater 21 of stage 2 and at the same time the stage 2 is moved up to the processing position, thereby defining the processing space 38. Further, an internal pressure of the processing container 1 is adjusted to be a predetermined pressure by a pressure control valve (not shown) of the exhaust mechanism 42.

Next, the valves 53e and 57e are opened. Accordingly, the carrier gas (N₂ gas) is supplied into the processing container 1 from the N₂ gas supply source 53a and 57a through the gas supply lines 53b and 57b, respectively. Further, the valve 51e is opened. Accordingly, the Ru(DMBD)(CO)₃ gas is supplied into the processing container 1 through the gas supply line 51b from the Ru raw material gas supply source 51a (step S10). The Ru(DMBD)(CO)₃ gas is thermally decomposed, and the Ru film is deposited on the wafer W in the processing container 1. Further, the SiH₄ gas is supplied to the gas supply line 55b from the SiH₄ gas supply source 55a with the valve 55e closed. Accordingly, the SiH₄ gas is stored in the storage tank 55d, so the internal pressure of the storage tank 55d is increased.

When a predetermined time passes after the valve Me is opened, the valve Me is closed. Thus, supply of the Ru(DMBD)(CO)₃ gas into the processing container 1 is stopped. In this case, since the carrier gas is supplied into the processing container 1, the Ru(DMBD)(CO)₃ gas remaining in the processing container 1 is discharged to the exhaust pipe 41, whereby an internal atmosphere of the processing container 1 changes from an atmosphere of the Ru(DMBD)(CO)₃ gas to an atmosphere of the N₂ gas (step S11).

When a predetermined time passes after the valve Me is closed, the valve 55e is opened. Thus, the SiH₄ gas stored in the storage tank 55d is supplied into the processing container 1 through the gas supply line 55b (step S20). An Si is introduced to the Ru film deposited on the wafer W in the processing container 1.

When a predetermined time passes after the valve 55e is opened, the valve 55e is closed. Thus, supply of the SiH₄ gas into the processing container 1 is stopped. In this case, since the carrier gas is supplied into the processing container 1, the SiH₄ gas remaining in the processing container 1 is discharged to the exhaust pipe 41, whereby the internal atmosphere of the processing container 1 changes from an SiH₄ gas atmosphere to an N₂ gas atmosphere (step S21). Meanwhile, as the valve 55e is closed, the SiH₄ gas supplied to the gas supply line 55b from the SiH₄ gas supply source 55a is stored in the storage tank 55d, so the internal pressure of the storage tank 55d is increased.

By performing the aforementioned cycle one time, a thin RuSi film is formed on the wafer W. Further, by repeating the cycle a predetermined number of times, the RuSi film with a desired thickness is formed. Thereafter, the wafer is unloaded from the processing container 1 in the reverse order of that when the wafer W is loaded into the processing container 1.

Further, an example of film-forming conditions when the RuSi film is formed on the wafer W using the film-forming apparatus 100 is as follows.

### <Film-Forming Condition>

(Step S10)

Method of supplying gas: Continuous flow

Step time: 2 to 16 seconds

Wafer temperature: 200 to 300 degrees C.

Pressure inside processing container: 400 to 667 Pa

Flow rate of Ru(DMBD)(CO)₃ gas: 129 to 200 sccm

(Step S20)

Method of supplying gas: Fill-flow

Step time: 0.05 to 0.8 seconds

Wafer temperature: 200 to 300 degrees C.

Internal pressure of processing container: 400 to 667 Pa

Flow rate of SiH₄ gas: 25 to 300 sccm

(Step S30)

Set number of times (Number of time of repeating step S10 and step S20): 35 to 280 times

### First Embodiment

### First Embodiment

The RuSi film is formed on a surface of an insulating film formed on the waver W using the film-forming apparatus 100, by changing a ratio of the supply amount of the SiH₄ gas to the supply amount of the Ru(DMBD)(CO)₃ gas using the aforementioned method of forming the RuSi film. The insulating film is a layered film formed by stacking an SiO₂ film and an Al₂O₃ film in this order. Further, the ratio of Si in the formed RuSi film and the resistivity of the RuSi film is measured.

In detail, the RuSi film is formed by changing the supply time of Ru(DMBD)(CO)₃ gas per cycle (the time of step S10), and the set number of times such that a total supply time of Ru(DMBD)(CO)₃ gas became 560 seconds in a plurality of cycles. Further, the flow rate of SiH₄ gas in step S20 is changed to 100 sccm, 200 sccm, and 300 scm. Combinations of the time of step S10 and the set number of times is shown in the following table 1.

TABLE 1

| | Supply time of Ru (DMBD)(CO)₃ gas | | | | |
|---|---|---|---|---|---|
| | per cycle [sec/cycle] | | | | |
| | 2 | 4 | 8 | 16 | 560 |
| Set number of time [times] | 280 | 140 | 70 | 35 | 0 |
| Total supply time of | 560 | 560 | 560 | 560 | 560 |
| Ru (DMBD)(CO)₃ gas [sec] | | | | | |

Further, other film-forming conditions are as follows.

### <Film-Forming Condition>

(Step S10)

Method of supplying gas: Continuous flow

Wafer temperature: 225 degrees C.

Internal pressure of processing container: 400 Pa

Flow rate of Ru(DMBD)(CO)₃ gas: 129 sccm

Flow rate of N₂ gas: 6000 sccm

(Step S20)

Method of supplying gas: Fill-flow

Step time: 0.05 seconds

Wafer temperature: 225 degrees C.

Internal pressure of processing container: 400 Pa

Flow rate of N₂ gas: 6000 sccm

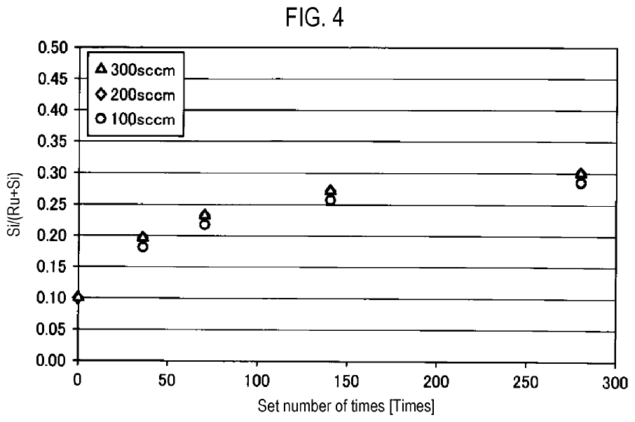

FIG. 4 is a diagram showing a relationship between the set number of times and the ratio of Si in the RuSi film. In FIG. 4, the set number of times [times] is shown on the horizontal axis and Si/(Ru+Si) is shown on the vertical axis. Further, the results when the flow rate of SiH₄ gas is 100 sccm, 200 sccm, and 300 sccm are indicated by a circle (◯), a diamond (⋄), and a triangle (Δ), respectively.

As shown in FIG. 4, it can be seen that it is possible to control Si/(Ru+Si) by changing the set number of times for any of the flow rates of the SiH₄ gas. In detail, it is possible to increase Si/(Ru+Si) by increasing the set number of times, that is, the ratio of the supply amount of the SiH₄ gas to the supply amount of the Ru(DMBD)(CO)₃ gas. Meanwhile, it is possible to decrease Si/(Ru+Si) by decreasing the set number of times, that is, the ratio of the supply amount of the SiH₄ gas to the supply amount of the Ru(DMBD)(CO)₃ gas.

As described above, according to the method of forming a RuSi film of an embodiment of the present disclosure, it is possible to easily control Si/(Ru+Si) in a RuSi film.

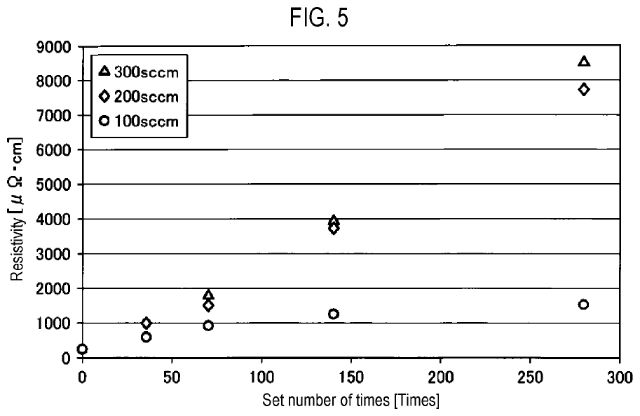

FIG. 5 is a diagram showing a relationship between a set number of times and a resistivity of the RuSi film. In FIG. 5, the set number of time [times] is shown on the horizontal axis and the resistivity [μΩ·cm] of the RuSi film is shown in the vertical axis. Further, the results when the flow rate of the SiH₄ gas is 100 sccm, 200 sccm, and 300 sccm are indicated by a circle (◯), a diamond (⋄), and a triangle (Δ), respectively.

As shown in FIG. 5, it can be seen that it is possible to control the resistivity of the RuSi film by changing the set number of times for any of the flow rates of the SiH₄ gas. In detail, it is possible to increase the resistivity of the RuSi film by increasing the set number of times, that is, the ratio of the supply amount of the SiH₄ gas to the supply amount of the Ru(DMBD)(CO)₃ gas. Meanwhile, it is possible to decrease the resistivity of the RuSi film by decreasing the set number of times, that is, the ratio of the supply amount of the SiH₄ gas to the supply amount of the Ru(DMBD)(CO)₃ gas.

As described above, according to the method of forming a RuSi film of the embodiment of the present disclosure, it is possible to easily control the resistivity of a RuSi film.

### Second Embodiment

The RuSi film is formed on a surface of an insulating film formed on the wafer W using the film-forming apparatus 100, by changing the ratio of the supply amount of the SiH₄ gas to the supply amount of the Ru(DMBD)(CO)₃ gas and the total supply time of the Ru(DMBD)(CO)₃ gas using the method of forming the RuSi film described above. The insulating film is a layered film formed by stacking an SiO₂ film and an Al₂O₃ film in this order. Further, a film thickness of the formed RuSi film is measured.

In detail, the total supply time of the Ru(DMBD)(CO)₃ gas is set as 60 seconds, 120 seconds, 280 seconds, 560 seconds, and 1200 seconds in a plurality of cycles. Further, for each case, similar to the first embodiment, the RuSi film is formed by changing the supply time of the Ru(DMBD)(CO)₃ gas per cycle (the time of step S10), and the set number of times. Combinations of the time of step S10 and the set number of times is shown in the aforementioned table 1.

Further, other film-forming conditions are as follows.

<Film-Forming Condition>

(Step S10)

Method of supplying gas: Continuous flow

Wafer temperature: 225 degrees C.

Internal pressure of processing container: 400 Pa

Flow rate of Ru(DMBD)(CO)₃ gas: 129 sccm

Flow rate of N₂ gas: 6000 sccm

(Step S20)

Method of supplying gas: Fill-flow

Step time: 0.05 seconds

Wafer temperature: 225 degrees C.

Internal pressure of processing container: 400 Pa

Flow rate of SiH₄ gas: 100 sccm

Flow rate of N₂ gas: 6000 sccm

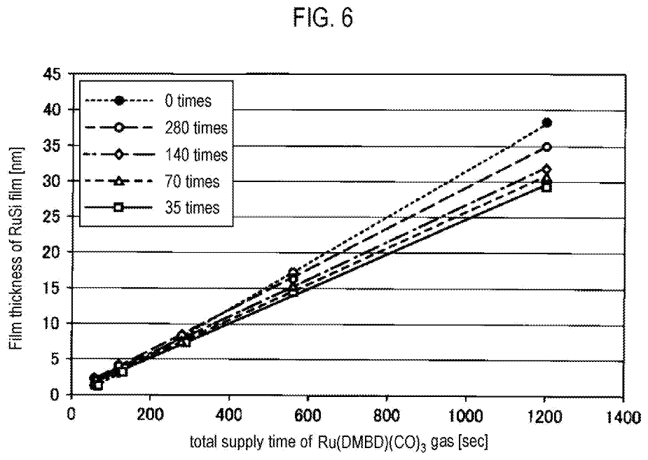

FIG. 6 is a diagram showing a relationship between the total supply time of the Ru(DMBD)(CO)₃ gas and a film thickness of the RuSi film. In FIG. 6, the total supply time [sec] of the Ru(DMBD)(CO)₃ gas is shown on the horizontal axis and the film thickness [nm] of the RuSi film is shown on the vertical axis. Further, the results when the set number of times is 280, 140, 70, 35, and 0 are indicated by a circle (◯), a diamond (⋄), a triangle (Δ), a rectangle (□), and a solid circle (●), respectively.

As shown in FIG. 6, it can be seen that the film thickness of the RuSi film changes in proportion to the total supply time [sec] of the Ru(DMBD)(CO)₃ gas for any of the set numbers of times. According to this result, in detail, by increasing the total supply time [sec] of the Ru(DMBD)(CO)₃ gas, it is possible to increase the film thickness of the RuSi film. Meanwhile, by decreasing the total supply time [sec] of the Ru(DMBD)(CO)₃ gas, it is possible to decrease the film thickness of the RuSi film.

As described above, according to the method of forming the RuSi film of the embodiment of the present disclosure, it is possible to easily control the film thickness of the RuSi film.

### First Comparative Example

The RuSi film is formed by simultaneously supplying the Ru(DMBD)(CO)₃ gas and the SiH₄ gas to a surface of an insulating film formed on a wafer W, using the film-forming apparatus 100. Further, the resistivity of the formed RuSi film is measured. The film-forming condition when forming the RuSi film is as follows.

<Film-Forming Condition>

Wafer temperature: 225 degrees C., 275 degrees C.

Internal pressure of processing container: 3 Torr(400 Pa)

Flow rate of Ru(DMBD)(CO)₃ gas: 129 sccm

Flow rate of SiH₄ gas: 0, 25, 50, 100, 300 sccm

Flow rate of N₂ gas: 6000 sccm

As the result of forming the RuSi film by simultaneously supplying the Ru(DMBD)(CO)₃ gas and the SiH₄ gas to a surface of an insulating film formed on the wafer W, the resistivity of the RuSi film exceeds an upper measurement limit under most conditions, so it cannot be measured. From this result, it can be seen that when the Ru(DMBD)(CO)₃ gas and the SiH₄ are simultaneously supplied to the surface of the insulating film formed on the wafer W, the resistivity of the RuSi film is very high and a controllability of the resistivity of the RuSi film is poor.

Further, in the aforementioned embodiments, the step S10 is an example of the first step, and the step S20 is an example of the second step. Further, the Ru raw material gas supply source Ma, the gas supply line Mb, the flow rate controller Mc, and the valve Me are an example of a first gas supply. Further, the SiH₄ gas supply source 55a, the gas supply line 55b, the flow rate controller 55c, the storage tank 55d, and the valve 55e are an example of a second gas supply.

The embodiments disclosed above should be construed as examples, not limiting in all terms. The embodiments described above may be omitted, replaced, and changed in various ways without departing from the accompanying claims and the subject thereof.

In the embodiments described above, the semiconductor wafer is exemplarily described as the substrate, the semiconductor wafer may be a silicon wafer and a semiconductor wafer of a compound of GaAs, SiC, GaN, and the like. Further, the substrate is not limited to the semiconductor wafer and may be a glass substrate, a ceramic substrate, or the like that is used for a FPD (flat panel display) such as a liquid crystal display.

In the embodiments described above, although a single wafer processing apparatus that processes wafers one by one is exemplarily described, the present disclosure is not limited thereto. For example, a batch type apparatus that processes a plurality of wafers at a time may be used.

According to the present disclosure, it is possible to control a resistivity of a RuSi film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a RuSi film, comprising performing a process a plurality of times, the process including alternately repeating:
supplying a Ru(DMBD)(CO)₃ gas into a processing container accommodating a substrate; and
supplying a hydrogenated silicon gas into the processing container.

2. The method of claim 1, wherein the supplying the hydrogenated silicon gas includes supplying the hydrogenated silicon gas that is stored in a storage tank into the processing container by opening and closing a valve disposed between the processing container and the storage tank.

3. The method of claim 2, wherein the supplying the Ru(DMBD)(CO)₃ gas includes supplying the Ru(DMBD)(CO)₃ gas into the processing container continuously.

4. The method of claim 3, wherein the supplying the Ru(DMBD)(CO)₃ gas includes supplying the Ru(DMBD)(CO)₃ gas into the processing container without storing the Ru(DMBD)(CO)₃ gas in the storage tank.

5. The method of claim 4, wherein the supplying the Ru(DMBD)(CO)₃ gas and the supplying the hydrogenated silicon gas are performed while the substrate is heated to 200 to 300 degrees C.

6. The method of claim 5, an insulating film is formed on the substrate.

7. The method of claim 6, wherein the hydrogenated silicon gas includes at least one gas selected from the group of SiH₄ and Si₂H₆.

8. The method of claim 1, wherein the supplying the Ru(DMBD)(CO)₃ gas includes supplying the Ru(DMBD)(CO)₃ gas into the processing container continuously.

9. The method of claim 1, wherein the supplying the Ru(DMBD)(CO)₃ gas includes supplying the Ru(DMBD)(CO)₃ gas that is stored in a storage tank into the processing container by opening and closing a valve disposed between the processing container and the storage tank.

10. The method of claim 1, wherein the supplying the Ru(DMBD)(CO)₃ gas and the supplying the hydrogenated silicon gas are performed while the substrate is heated to 200 to 300 degrees C.

11. The method of claim 1, an insulating film is formed on the substrate.

12. The method of claim 1, wherein the hydrogenated silicon gas includes at least one gas selected from the group of SiH₄ and Si₂H₆.

13. A film-forming apparatus comprising:
a processing container accommodating a substrate;
a first gas supply configured to supply a Ru(DMBD)(CO)₃ gas into the processing container;
a second gas supply configured to supply a hydrogenated silicon gas into the processing container; and
a controller,
wherein the controller is configured to control the first gas supply and the second gas supply to perform a process a plurality of times, the process including alternately repeating supplying the Ru(DMBD)(CO)₃ gas into the processing container and supplying the hydrogenated silicon gas into the processing container.

14. A film-forming apparatus comprising:
a processing container accommodating a substrate;
a first gas supply configured to supply an Ru(DMBD)(CO)₃ gas into the processing container; and
a second gas supply configured to supply a hydrogenated silicon gas into the processing container,
wherein a storage tank configured to store the Ru(DMBD)(CO)₃ gas is not provided in the first gas supply, and a storage tank configured to store the hydrogenated silicon gas is provided in the second gas supply.
